(19) United States
(12) Patent Application Publication
(10) Pub. No.: US 2006/0119369 A1
(43) Pub. Date: Jun. 8, 2006

(54) Capacity detecting sensor

(75) Inventors: Ken Kawahata, Miyagi-ken (JP); Masahito Nakamura, Miyagi-ken (JP)

Correspondence Address: BEYER WEAVER & THOMAS LLP, P.O. BOX 70250, OAKLAND, CA, 94612-0250, US

(73) Assignee: ALPS ELECTRIC CO., LTD.

(21) Appl. No.: 11/261,154

(22) Filed: Oct. 27, 2005

(30) Foreign Application Priority Data
Dec. 3, 2004 (JP) 2004-351615

(51) Int. Cl. G01R 27/26

(52) U.S. Cl. 324/662

(57) ABSTRACT

The electrostatic capacity detecting sensor includes first electrodes which extend from column wiring lines, second electrodes which extend from row wiring lines and are formed on a layer different from that of the first electrodes, a third electrode which is electrically independent from the first electrode and the second electrode through an insulating film, a first electrostatic capacity region C1 formed between the first electrodes and the third electrode, and a second electrostatic capacity region C2 formed between the second electrodes and the third electrode.

### BACKGROUND OF THE INVENTION

1. Field of the Invention

The present invention relates to a sensor that measures indiscernible irregularities of an electrostatic object to be measured, and, more particularly, to an electrostatic capacity detecting sensor, in which disconnection of wiring lines due to electrostatic discharge rarely occurs, and which can obtain a detecting signal having a large S/N ratio and a high resolution.

2. Description of the Related Art

As a sensor that captures capacity change between a detecting electrode and a fingerprint as a signal and detects the fingerprint, for example, a sensor described in JP-A-2003-207306 is known. The sensor described in JP-A-2003-207306 includes the electrically floated detecting electrode and two electrodes capacitively connected to the detecting electrode in series. When a signal inputted to one electrode is outputted from the other electrode, the sensor reads a signal, in which a capacity changes due to the mountain and valley of the fingerprint and the detecting electrode to detect the fingerprint.

However, in a technology described in JP-A-2003-207306, if the width of a wiring connected to the electrode is narrow in order to detect an indiscernible shape such as the fingerprint with a high resolution, disconnection is likely to occur due to electrostatic discharge. In order to solve this problem, if the width of the wiring increases while maintaining the high resolution, a ratio of electrode area contributing to the capacity change is reduced and thus an S/N ratio of a detecting signal is reduced.

Furthermore, when the width of the wiring is narrow, a response is delayed. In particular, when the wiring is made of indium-tin-oxide (hereinafter, referred to as ‘ITO’) which is a high-resistance material in order to make the sensor transparent, response delay due to the narrow wiring width remarkably increases.

### SUMMARY OF THE INVENTION

The present invention has been finalized in view of the above problems, and it is an object of the invention to provide an electrostatic capacity detecting sensor, in which disconnection of wiring lines due to electrostatic discharge rarely occurs and which can obtain a detecting signal having a large S/N ratio and a high resolution.

In order to solve the problems, there is provided an electrostatic capacity detecting sensor in which a row wiring and a column wiring are arranged in a matrix on a substrate, including: at intersections between the row wiring lines and the column wiring lines, first electrodes which extend from the row wiring; second electrodes which extend from the column wiring lines and are provided on a different layer from that of the first electrode; a third electrode which is electrically independent from the first electrode and the second electrode through an insulating film; a first electrostatic capacity region formed between the first electrode and the third electrode; and a second electrostatic capacity region formed between the second electrode and the third electrode. In this sensor, the change in distance between an object to be detected and the third electrode is detected by the change of displacement current between the first electrode and the second electrode.

In the electrostatic capacity detecting sensor, the third electrode can be formed above the first electrode and the second electrode.

In addition, in the electrostatic capacity detecting sensor, the third electrode can be formed between the first electrode and the second electrode through the insulating film.

Furthermore, in the electrostatic capacity detecting sensor, a portion of the third electrode can be exposed to a surface through a contact hole formed in the insulating film.

Still furthermore, in the electrostatic capacity detecting sensor, the third electrode can extend vertically to surround an upper electrode of the first electrode and the second electrode.

Still furthermore, in the electrostatic capacity detecting sensor, the third electrode can be formed on the same layer of the upper electrode of the first electrodes and the second electrodes and on a layer located higher than the upper electrode while conducted to one another.

Still furthermore, in the electrostatic capacity detecting sensor, a protective film can be further provided at the surface.

Still furthermore, in the electrostatic capacity detecting sensor, the substrate can be made of a transparent material, and the first electrode, the second electrode, and the third electrode can be made of a transparent conductive material.

### BRIEF DESCRIPTION OF THE DRAWINGS

FIG. 1 is a conceptual view showing a construction of an equivalent circuit of an electrostatic capacity detecting sensor according to a first embodiment of the present invention;

FIG. 2 is an enlarged plan view of a detecting portion of the capacity detecting sensor of FIG. 1;

FIG. 3 is a cross-sectional view taken along line III-III of FIG. 2;

FIG. 4 is a conceptual view showing a construction of an I/V converting circuit 20 in the electrostatic capacity detecting sensor 11, which converts a capacitor of a detecting portion and displacement current flowing in the capacitor into a voltage;

FIG. 5 is a conceptual view showing a construction of an I/V converting circuit 20 in the electrostatic capacity detecting sensor 11, which converts a capacitor of a detecting portion and displacement current flowing in the capacitor into a voltage;

FIG. 6 is a graph showing a relationship between an output voltage and a line width of a driving electrode 12;

FIG. 7 is an enlarged plan view of a detecting portion of a capacity detecting sensor according to a second embodiment of the invention;

FIG. 8 is a cross-sectional view taken along line VIII-VIII of FIG. 7;

FIG. 9 is a cross-sectional view taken along line IX-IX of FIG. 7;

FIG. 10 is a cross-sectional view of a detecting portion of a capacity detecting sensor according to a third embodiment of the invention;

FIG. 11 is a view explaining an operation of a driving electrode of the electrostatic capacity detecting sensor according to the third embodiment of the invention;

FIG. 12 is an enlarged plan view of a detecting portion of a capacity detecting sensor according to a fourth embodiment of the invention;

FIG. 13 is a cross-sectional view taken along line XIII-XIII of FIG. 12;

FIG. 14 is an enlarged plan view of a detecting portion of an electrostatic capacity detecting sensor according to a fifth embodiment of the invention;

FIG. 15 is a cross-sectional view taken along line XIV-XIV of FIG. 14;

FIG. 16 is a perspective view showing a portable phone including the electrostatic capacity detecting sensor according to the invention;

FIG. 17 is an enlarged plan view showing an example of a detecting portion of an electrostatic capacity detecting sensor in the related art; and

FIG. 18 is a cross-sectional view taken along line XVIII-XVIII of FIG. 17.

### DESCRIPTION OF THE PREFERRED EMBODIMENT

Hereinafter, an electrostatic capacity detecting sensor according to the present invention will be described with reference to the drawings.

### First Embodiment

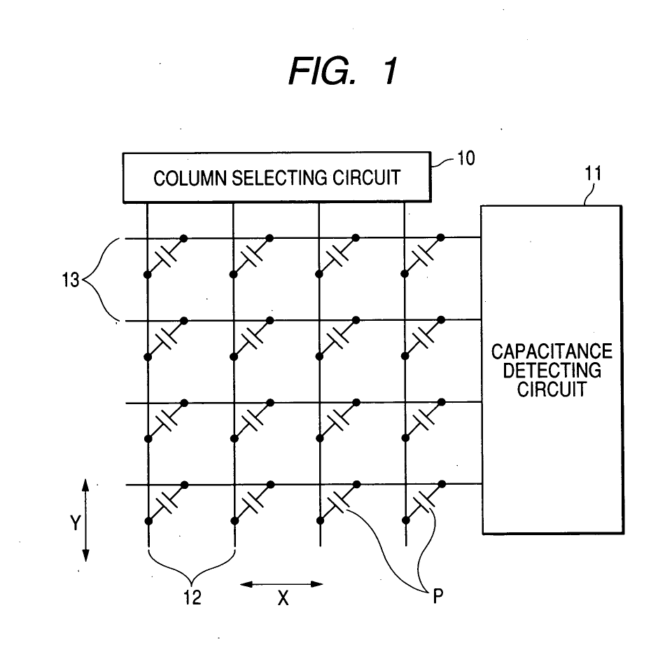

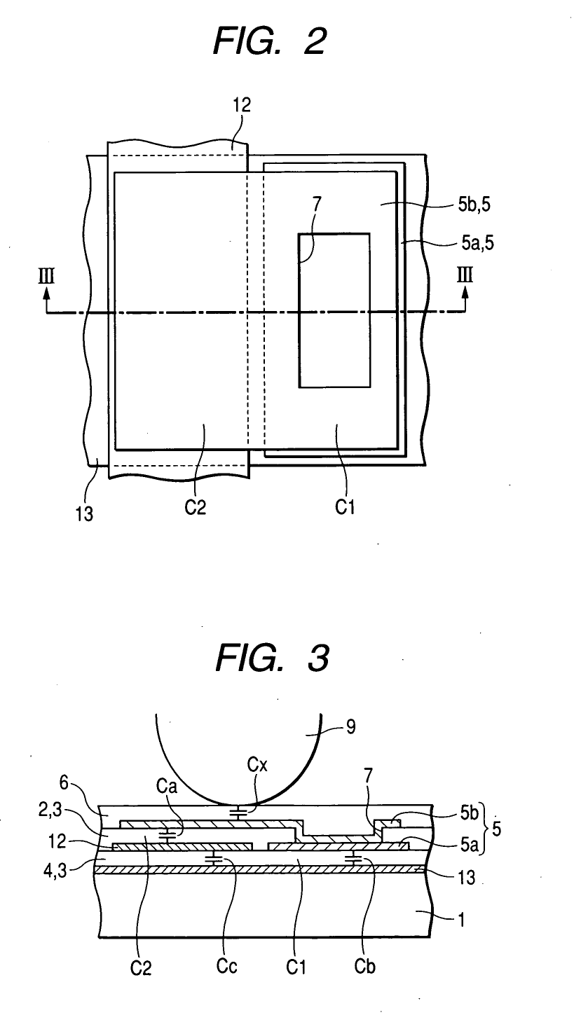

FIG. 1 is a conceptual view showing a construction of an equivalent circuit of an electrostatic capacity detecting sensor according to a first embodiment of the invention, FIG. 2 is an enlarged plan view of a detecting portion of the capacity detecting sensor of FIG. 1, and FIG. 3 is a cross-sectional view taken along line III-III of FIG. 2.

The electrostatic capacity detecting sensor according to the embodiment, as shown in FIGS. 1 to 3, includes a plurality of detecting electrodes 13 (first electrode), row wiring lines which are arranged in a first direction X, a plurality of driving electrodes 12 (second electrode), column wiring lines which are arranged in a second direction Y, and a floating electrode 5 (third electrode) which is electrically independent from the detecting electrodes 13 and the driving electrodes 12 through an insulating film 3. The insulating film 3 includes a first interlayer insulating film 4 and a second interlayer insulating film 2. In the electrostatic capacity detecting sensor according to the embodiment, a portion of the floating electrode 5 viewed in a plan view is a detecting portion of an object to be detected (hereinafter, referred to as pixel P).

The detecting electrode 13 shown in FIG. 3 is composed of a first conductive film and formed on a transparent glass substrate 1. As shown in FIG. 3, a driving electrode 12 composed of a second conductive film is formed on the detecting electrode 13 through the first interlayer insulating film 4. The floating electrode 5 includes a lower electrode 5a composed of a second conductive film formed on the same plane as the driving electrode 12 and an upper electrode 5b composed of a third conductive film formed on the driving electrode 12 through the second interlayer insulating film 2. As shown in FIG. 3, a portion of the upper electrode 5b is exposed to the surface of the second interlayer insulating film 2 through a contact hole 7 formed in the second interlayer insulating film 2 and is conducted with the lower electrode 5a. In addition, a passivation film 6 (protective film) is provided on the upper electrode 5b. The passivation film 6 protects the third conductive film from the external environment (moisture, etc.) when the third conductive film is formed of a metal film or the like weak to moisture.

The first to third conductive films are made of ITO. The insulating film 3 and the passivation film 6 are formed by laminating SiₓN_{y} (silicon nitride film) such as Si₃N₄.

In addition, as shown in FIGS. 2 and 3, the driving electrode 12 and the upper electrode 5b overlap in a plane, and the detecting electrode 13 and the lower electrode 5a overlap in a plane. Further, as shown in FIG. 3, a second electrostatic capacity region C2 is formed between the driving electrode 12 and the upper electrode 5b, and a first electrostatic capacity region C1 is formed between the detecting electrode 13 and the lower electrode 5a.

For example, when detecting a fingerprint, since requiring a location resolution of 500 dpi or more and a detection area of about 10 mm², the detecting electrodes 13, the row wiring lines shown in FIG. 1, are composed of the 0.1 μm-thick ITO film, the first conductive layer, and 200 detecting electrodes are formed on the 0.7 mm-thick glass substrate 1 with a pitch of 30 to 100 μm, for example, 50 μm. The respective detecting electrodes 13 are connected to the capacity detecting circuit 11 that detects electrostatic capacity.

Moreover, the driving electrodes 12, the column wiring lines, are composed of the 0.1 μm-thick ITO film, the second conductive film, and 200 driving electrodes 12 are formed on the first interlayer insulating film 4 with a pitch of 30 to 100 μm, for example, 50 μm. The respective driving electrodes 12 are connected to a column selecting circuit 10. The column selecting circuit 10 connects the electrodes except the driving electrode 12 selected upon measuring the capacity to ground.

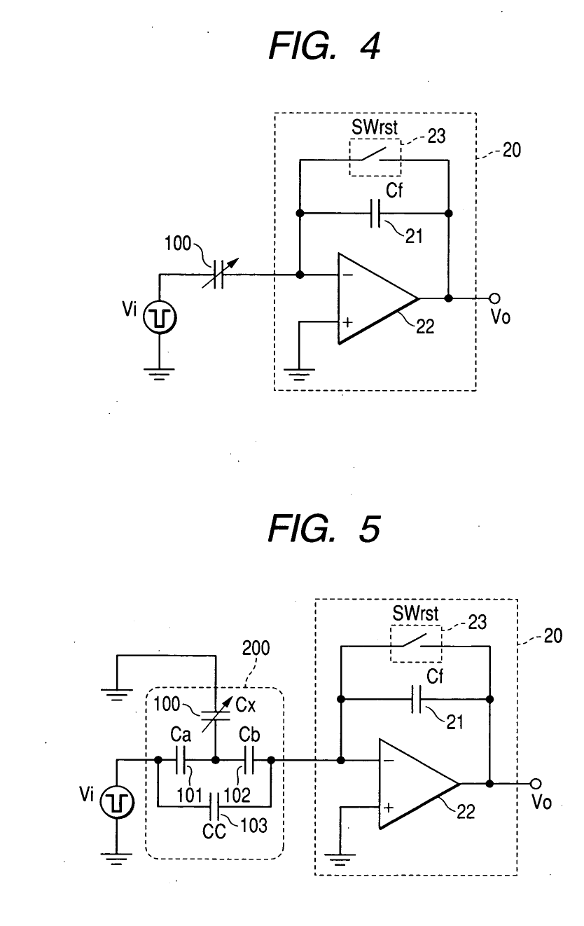

Next, an operation of the electrostatic capacity detecting sensor according to the first embodiment will be described with reference to FIGS. 4 and 5.

With the above structure, capacity occurs between the driving electrode 12 and the floating electrode 5 and between the detecting electrode 13 and the floating electrode 5 in each pixel P, and the equivalent circuit is expressed like FIG. 1. In order to measure each capacity from the circuit like the above, the circuit like FIG. 4 is generally used. That is, in the capacity detecting circuit 11, an I/V converting circuit 20 is provided in each of the detecting electrodes 13, the row wiring lines, and displacement current flows into a capacitor 100, then the I/V converting circuit 20 composed of an operational amplifier 22 and a capacitor 21 converts a current value of the displacement current into a voltage value and outputs the voltage value as an output Vo. At this time, the output Vo is expressed by Equation 1 described below.

$$\begin{matrix}Equation 1 & \\ Vo = - \frac{Cx}{Cf} Vi & ( 1 )\end{matrix}$$

In this case, charges accumulated in the capacitor 21 are discharged by turning a switch 23 on after measurement, and the switch 23 is turned off upon the measurement.

However, in the embodiment, the capacity to be measured is changed by a coupling capacity between the object to be detected 9 and the floating electrode 5.

Accordingly, the capacitor 100 of FIG. 4 is replaced with the equivalent circuit of a capacitor 200 shown in FIG. 5.

At this time, the output is expressed by Equation 2.

$$\begin{matrix}Equation 2 & \\ Vo = - \frac{\frac{Ca \times Cb}{Ca + Cb + Cx} + Cc}{Cf} Vi & ( 2 )\end{matrix}$$

In this case, as shown in FIG. 3, a capacity value Ca is the capacity value of a capacitor 101 between the driving electrode 12 and the floating electrode 5, and a capacity value Cb is the capacity value of a capacitor 102 between the detecting electrode 13 and the floating electrode 5. A capacity value Cc is the capacity value of a parasitic capacitor 103 between the driving electrode 12 and the detecting electrode 13. A capacity value Cx is the capacity value of the capacitor 100 between the floating electrode 5 and the object to be detected 9.

In an ideal case, the capacity value Cx=0 when the object to be detected 9 is sufficiently separated from the floating electrode 5, and the output Vo is expressed by Equation 3 described below.

$$\begin{matrix}Equation 3 & \\ Vo ( off ) = - \frac{\frac{Ca \times Cb}{Ca + Cb} + Cc}{Cf} Vi & ( 3 )\end{matrix}$$

In addition, the capacity value Cx=CO when the object to be detected 9 is sufficiently close to or contact the floating electrode 5, and the output Vo is expressed by Equation 4 described below.

$$\begin{matrix}Equation 4 & \\ V0 = ( on ) = - \frac{\frac{Ca \times Cb}{Ca + Cb + C0} + Cc}{Cf} Vi & ( 4 )\end{matrix}$$

In this case, the object to be detected 9, the floating gate 5, and the passivation film 6 interposed therebetween form a parallel plate capacity having the size of the floating electrode 5 viewed in plan, and the capacity value C0 is obtained from the thickness of the passivation film 6, the area of the floating electrode 5, and the permittivity of a dielectric material.

That is, the output voltage Vo due to the displacement current flowing in the I/V converter 20 is reduced by the fact that the displacement current outputted from the capacitor 102 (capacity value Cb) is divided by the capacitor 101 (capacity value Ca) and the capacitor 100 (capacity Cx) when the object to be detected 9 comes close to the passivation film 6, and Cx comes close to Cx.

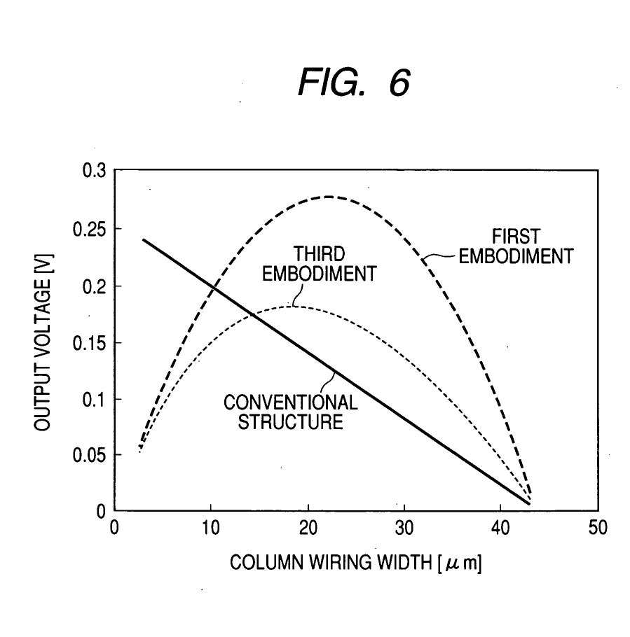

When, SiₓN_{y}(silicon nitride film: permittivity ε=7) is used as the material of the insulating film 3 and the passivation film 6, the thickness of which is 300 nm, and the floating electrode 5 is 50 μm×50 μm in the shape shown in FIGS. 2 and 3, the relationship between the line width and the output voltage of the driving electrode 12 becomes like FIG. 6. As shown in FIG. 6, the line width of the driving electrode 12 is 22 μm when the output voltage becomes the maximum. At this time, the capacity value Ca (capacitor 101) and the capacity Cb (capacitor 102) are equal to each other. When the line width of the driving electrode 12 is in the range of 12 to 32 μm, a sufficiently large output voltage, 0.22 V or more, can be obtained. On the other hand, when the line width of the driving electrode 12 is less than 12 μm, the first electrostatic capacity region C1 is reduced and the output voltage is reduced. Furthermore, when the line width of the driving electrode 12 is greater than 32 μm, the second electrostatic capacity region C2 is reduced and the output voltage is reduced.

For example, the capacity values are Ca=214 fF, Cb=214 fF, Cc=214 fF, and C0=456 fF when the output voltage becomes the maximum in FIG. 6. In addition, if the capacity value Cf=1 pF and V1=5 V, Vo(off)=1.60 V when the object to be detected 9 is sufficiently separated from the passivation film 6, and Vo(on)=1.33 V when the object to be detected 9 contacts the passivation film 6, thereby, the output change, that is, a voltage difference varying with the existence of the object to be detected ΔVo=0.28 V can be obtained.

Furthermore, in the electrostatic capacity detecting sensor according to the embodiment, the output Vo changes monotonously from the state in which the object to be detected 9 is sufficiently separated from the sensor surface (passivation film 6) to the state in which the object to be detected 9 contacts the sensor surface. Accordingly, the electrostatic capacity detecting sensor can output the detecting result at wide levels corresponding to the distance and read the fingerprint shape faithfully when the object to be detected is a fingerprint.

That is, when the object to be detected 9 (conductor such as a finger) contacts the surface of the electrostatic capacity detecting sensor according to the first embodiment, in the pixel P corresponding to a concave portion of the fingerprint, the floating electrode 5 and the object to be detected 9 are separated from each other at a predetermined distance, and the voltage value becomes the output Vo(off), thereby the voltage value barely changes from an initial voltage value when the object to be detected 9 is sufficiently separated from the sensor surface.

On the other hand, in the pixel P corresponding to a convex portion of the fingerprint, the floating electrode 5 contacts the object to be detected 9, and the voltage value becomes the output Vo(in), thereby a sufficient ΔVo from V(off) can be obtained.

The electrostatic capacity detecting sensor according to the embodiment can obtain the capacity change of the pixel P as the change of the displacement current by the above construction, as described by the equivalent circuit shown in FIGS. 4 and 5, and detect the capacity by the I/V converting circuit 20. Therefore, the shape of the irregular surfaces of the object to be detected 9 can be outputted as signal data by detecting the electrostatic capacity change generated when the fin irregular surfaces are pressed on the surface of the passivation film 6,

Although the I/V converting circuit 20 shown in FIG. 5 is used, thereby all driving electrodes 12 except the driving electrode selected by the column selecting circuit 10 are connected to ground (ground potential) upon the measurement, and all electrostatic capacities on the same detecting electrode 13 except the capacity to be measured are inputted in parallel to a gauge as a parasitic capacity, the capacity detecting circuit 11 can be cancelled by connecting the electrode opposite to the parasitic capacity to the ground.

With this construction, the indiscernible irregularities, that is, the indiscernible capacity change can be precisely detected. As the result, expensive material such as a semiconductor substrate is not required, and thus the cost can be reduced. In addition, even when the dot pitch is small, the sensitivity of the sensor can be improved by increasing the changing amounts of the capacity and the initial capacity of each dot.

Furthermore, the electrostatic capacity detecting sensor according to the embodiment includes the detecting electrodes 13, the row wiring; the driving electrodes 12, the column wiring provided on a layer different from that of the detecting electrodes 13; the floating electrode 5 electrically independent from the detecting electrodes 13 and the driving electrodes 12 through the insulating film 3; the first electrostatic capacity region C1 formed between the detecting electrode 13 and the floating electrode 5; and the second electrostatic capacity region C2 formed between the driving electrodes 12 and the floating electrode 5 and detects the change in distance between the object to be detected 9 and the floating electrode 5 by the change of the displacement current between the detecting electrode 13 and the driving electrode 12, thereby the first electrostatic capacity region C1 can be formed in a region in which the detecting electrode 13 and the driving electrode 12 overlap in a plane.

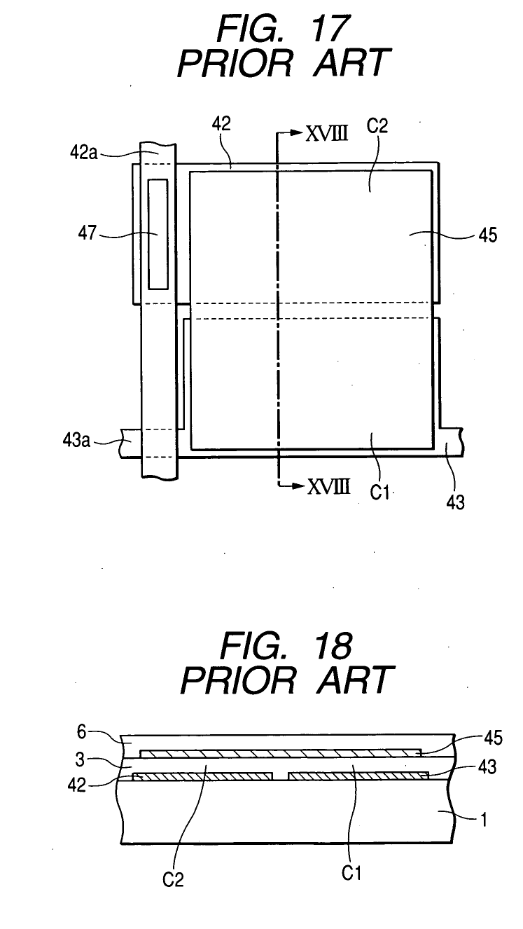

For example, in the electrostatic capacity detecting sensor in the related art described below, the first electrostatic capacity region C1 or the second electrostatic capacity region C2 cannot be formed in a region in which the detecting electrode 13 and the driving electrode 12 overlap in a plane. FIG. 17 is an enlarged plan view showing an example of a detecting portion of an electrostatic capacity detecting sensor in the related art, and FIG. 18 is a cross-sectional view taken along line XVIII-XVIII of FIG. 17. Meanwhile, in the related arts shown in FIGS. 17 and 18, the same portions as those of the first embodiment shown in FIGS. 1 to 3 are denoted by the same reference numerals, and thus their description will be omitted.

The electrostatic capacity detecting sensor shown in FIGS. 17 and 18 includes a detecting electrode 43, in which a portion of row wiring lines 43a are arranged widely; a driving electrode 42 adjacent to the detecting electrode 43 and conducted with a column wiring 42a through a contact hole 47; and a floating electrode 45 disposed on the driving electrode 42 and the detecting electrode 43 through an insulating film 3.

In the electrostatic capacity detecting sensor shown in FIGS. 17 and 18, there is no area in which the floating electrode 45 can be formed in a region in which the row wiring 43a (corresponding to the detecting electrode 13 of the invention) and the column wiring 42a (corresponding to the driving electrode 12 of the invention) overlap in a plane, thereby a first electrostatic capacity region C1 or a second electrostatic capacity region C2 cannot be formed. Accordingly, as shown in FIGS. 17 and 18, the first electrostatic capacity region C1 and the second electrostatic capacity region C2 must be formed on portions, at which the column wiring 42a does not exist. Thus, in order to widen the column wiring 42a, the first electrostatic capacity region C1 and the second electrostatic capacity region C2 must be small or the wiring interval between the column wiring lines 42a must be wide.

However, in the electrostatic capacity detecting sensor shown in FIGS. 17 and 18, if the first electrostatic capacity region C1 or the second electrostatic capacity region C2 is small, the ratio of the electrode area contributing to the capacity change is reduced and the S/N ratio of the level of the detecting signal is reduced. Furthermore, if the wiring interval between the column wiring lines 42a is widened, the resolution is deteriorated.

On the contrary, in the electrostatic capacity detecting sensor according to the embodiment, since the floating electrode 5 is formed and thus the capacity region C1 can be formed in the region in which the detecting electrode 13 and the driving electrode 12 overlap in a plane, the width of the column wiring can be increased up to the same width as that of the driving electrode 12 forming the first electrostatic capacity region C1 and the width of the row wiring can be increased up to the same width as that of the detecting electrode 13 forming the second electrostatic capacity region C2, without reducing the first electrostatic capacity region C1 or the second electrostatic capacity region C2 or widening the respective wiring intervals of the detecting electrodes 13 and the driving electrodes 12.

As the result, in the electrostatic capacity detecting sensor according to the embodiment, the width of the column wiring or the row wiring is wider than that of the electrostatic capacity detecting sensor in the related art, and thus disconnection of wiring lines due to the electrostatic discharge rarely occurs, comparing with the sensor in the related art. Further, since the first electrostatic capacity region C1 can be formed in the detecting electrode 13 and the driving electrode 12 overlap in a plane, the ratio of the electrode area contributing to the capacity change and the S/N ratio of the detecting signal can be larger than those of the sensor in the related art. Furthermore, since the column wiring or the row wiring can be widened without widening the respective wiring intervals of the detecting electrodes 13 and the driving electrodes 12, the resolution of the electrostatic capacity detecting sensor is not deteriorated. Still furthermore, since the column wiring or the row wiring can be wide, the response is not delayed even when the column wiring or the row wiring is made of ITO which is a high-resistance material in order to make the sensor transparent.

Still furthermore, since the electrostatic capacity detecting sensor according to the embodiment includes the passivation film 6 at the surface, the third conductive film can be protected from the external environment (moisture, etc.) when the metal film weak to moisture is used as the third conductive film. In addition, the surface strength becomes excellent and, residual fingerprints do not affect considerably when the sensor is used as a fingerprint sensor or the like.

Still furthermore, in the electrostatic capacity detecting sensor according to the embodiment, since the substrate is the transparent glass substrate 1 and the first to third conductive films are made of the ITO film, the entire electrostatic capacity detecting sensor can be transparent, and thus can be formed on a display surface of a portable apparatus.

### Second Embodiment

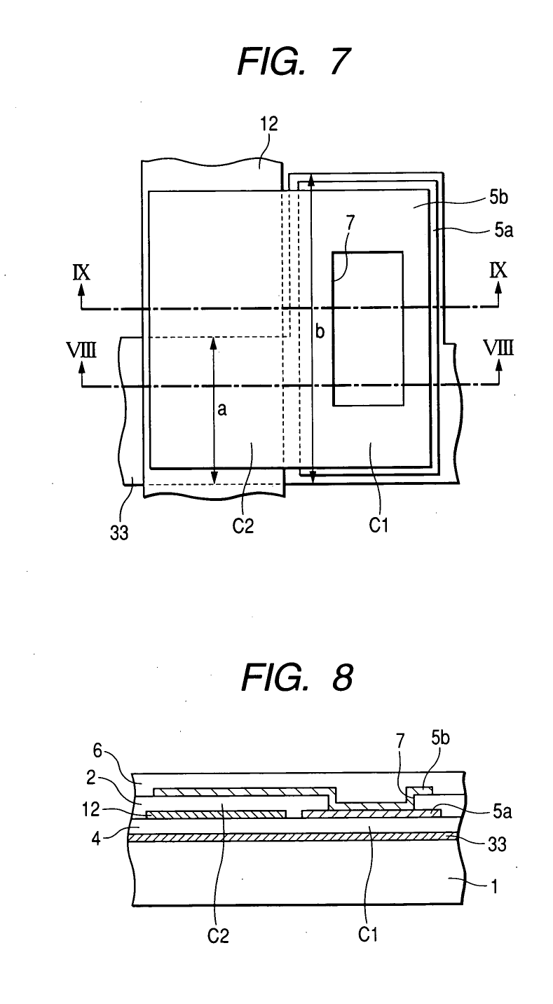

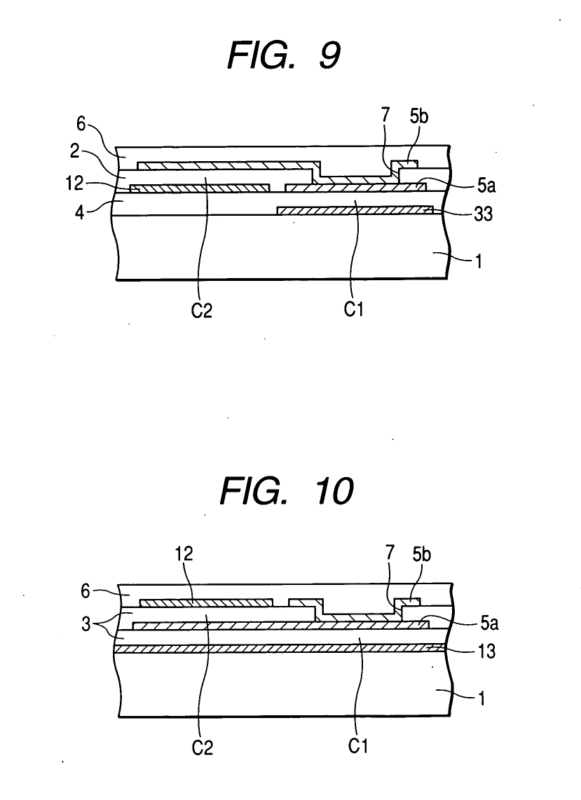

A second embodiment of the invention will be described with reference to FIGS. 7 to 9. FIG. 7 is an enlarged plan view of a detecting portion of a capacity detecting sensor according to a second embodiment of the invention, FIG. 8 is a cross-sectional view taken along line VIII-VIII of FIG. 7, and FIG. 9 is a cross-sectional view taken along line IX-IX of FIG. 7. The same portions as those of the first embodiment shown in FIGS. 1 to 3 are denoted by the same reference numerals, and thus, their description will be omitted.

The sensor shown in FIGS. 7 to 9 is different from the first embodiment in that the width a of a detecting electrode 33 composing a region in which the detecting electrode 33 and a driving electrode 12 overlap in a plane is narrower than the width b of the detecting electrode 33 of a region in which the detecting electrode 33 and a driving electrode 12 do not overlap in a plane.

With the electrostatic capacity detecting sensor like the above, a capacity value Cc of a parasitic capacitor 103 between the driving electrode 12 and the detecting electrode 13 is more reduced than that of the first embodiment. Therefore, in the driving electrode 12, a time constant is reduced by the reduction amount of the capacity value Cc, and thus the effect of the wiring delay can be reduced. Furthermore, the reduced width of the detecting electrode 33 increases the resistance, but the resistance is offset by reducing the capacity value Cc, thereby, the time constant barely changes. Here, the “time constant” of the column wiring (or the row wiring) is the value obtained by multiplying a resistance value of the column wiring (or the row wiring) by the capacity value Cc.

In addition, as shown in FIGS. 7 to 9, since the electrode area contributing to the capacity change is the same as that of the first embodiment, the S/N ratio of the level of the detecting signal is large like the first embodiment.

### Third Embodiment

A third embodiment of the invention will be described with reference to FIG. 10. FIG. 10 is a cross-sectional view of a detecting portion of a capacity detecting sensor according to a third embodiment of the invention. Meanwhile, in the capacity detecting sensor of the third embodiment according to the invention, the shapes of the respective members viewed in plan are almost the same as FIG. 2, and FIG. 10 is a cross-sectional view taken along line A-A of FIG. 2. In addition, in the third embodiment shown in FIG. 10, the same portions as those of the first embodiment shown in FIGS. 1 to 3 are denoted by the same reference numerals, and thus, their description will be omitted.

The sensor shown in FIG. 10 is different from the first embodiment in that a driving electrode 12 is composed of a third conductive film, and the floating electrode 5 is formed between a detecting electrode and the driving electrode 12 through an insulating film 3 by arranging a lower electrode 5a composed of a second conductive film over a floating electrode 5 when viewed in plan.

With the electrostatic capacity detecting sensor like the above, an electric field between the driving electrode 12 and the detecting electrode 13 can be shield and a capacity value Cc of a parasitic capacitor 103 between the driving electrode 12 and the detecting electrode 13 can be eliminated. Therefore, in the driving electrode 12 and the detecting electrode 13, a time constant and the effect of the wiring delay is further reduced, as compared with the first embodiment.

The relationship between the output voltage and the line width of the driving electrode 12 in the shape shown in FIG. 10 is shown in FIG. 6. In addition, for example, when the output voltage becomes the maximum in FIG. 10, the respective capacity values become Ca=175 fF, Cb=456 fF, Cc=1 fF, and C0=252 fF. Furthermore, if the capacity value Cf=1 pF and V1=5V, Vo(off)=0.64 V when an object to be detected 9 is sufficiently separated from a passivation film 6, and Vo(on)=0.46 V when the object to be detected 9 contacts the passivation film 6, thereby, the output change of the difference voltage varying with the existence of the object to be detected 9 ΔVo=0.18 V can be obtained.

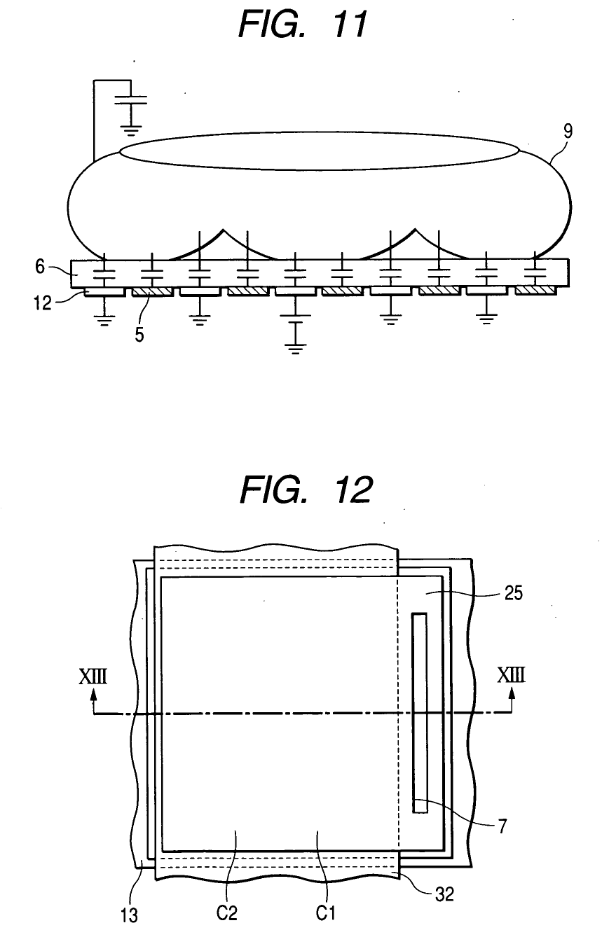

Still furthermore, as shown in FIG. 11, only one column of the driving electrodes 12 is in an active state, and the other columns of the driving electrodes 12 are fixed to a ground potential. In the electrostatic capacity detecting sensor shown in FIG. 10, since the driving electrode 12 is composed of the third conductive film and only the passivation film 6 is formed on the driving electrode 12, the surface potential of the object to be detected 9 can always be fixed to ground potential (earth) through the driving electrodes 12 not in an active state. Accordingly, a difference voltage varying with the existence of the object to be detected 9 can be increased and the sensitivity can be improved. Thus, external noise, for example, noise of a human body when the object to be detected 9 is a finger can be reduced. Also, a region in which the driving electrode 12 is provided can be used to reduce the noise.

### Fourth Embodiment

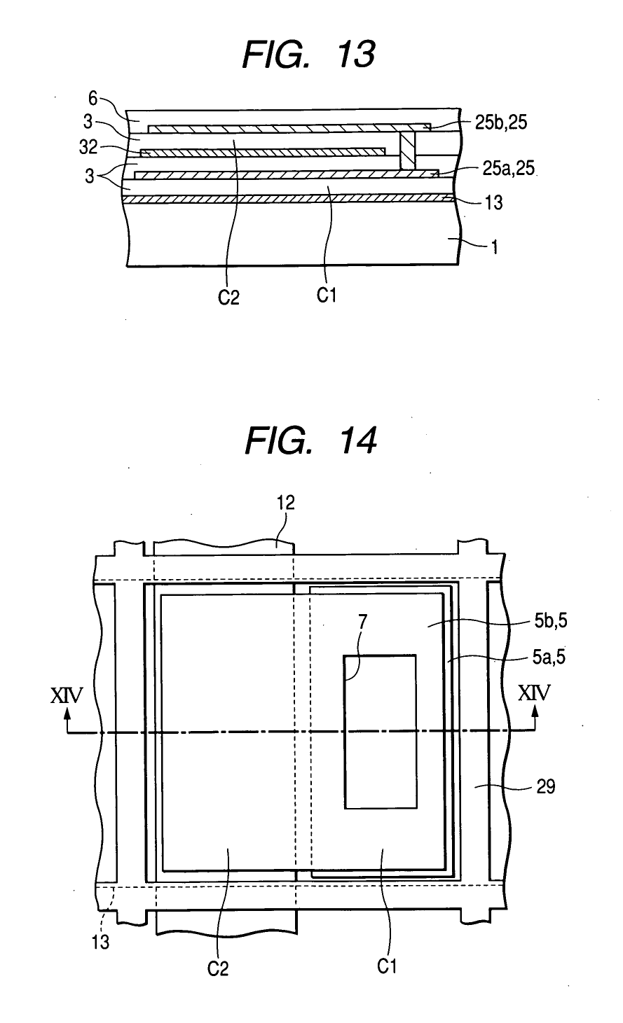

A fourth embodiment of the invention will be described with reference to FIGS. 12 and 13. FIG. 12 is an enlarged plan view of a detecting portion of a capacity detecting sensor according to a fourth embodiment of the invention, and FIG. 13 is a cross-sectional view taken along line D-D of FIG. 12. Meanwhile, in the fourth embodiment shown in FIGS. 12 and 13, the same portions as those of the first embodiment shown in FIGS. 1 to 3 are denoted by the same reference numerals, and thus, their description will be omitted.

The sensor shown in FIGS. 12 and 13 is different from the first embodiment in that a lower electrode 25a composed of a second conductive film and an upper electrode 25b composed of a fourth conductive film conducted with the lower electrode 25a by a contact hole 7 provided on an end are disposed over the floating electrode 5 when viewed in plan, a driving electrode 32 composed of a third conductive film is provided between the lower electrode 25a and the upper electrode 25b through an insulating layer 3, thereby the floating electrode 25 extends vertically to surround the driving electrode, and a region in which the detecting electrode 13 and the driving electrode 32 overlap in a plane is wider than that of the first embodiment. Accordingly, the fourth embodiment more includes another conductive film and insulating film 3 respectively than those of the first embodiment.

In the electrostatic capacity detecting sensor shown in FIGS. 12 and 13, since a first electrostatic capacity region C1 and a second electrostatic capacity region C2 are formed in a region in which the detecting electrode 13 and the driving electrode 32 overlap in a plane, the first electrostatic capacity region C1 and the second electrostatic capacity region C2 can be widened without widening the respective wiring intervals of the detecting electrodes 13 and the driving electrodes 12. Further, the width of the column wiring can be increased up to the width of the driving electrode 12 forming the first electrostatic capacity region C1, and the width of the row wiring can be increased up to the width of the detecting electrode 13 forming the second electrostatic capacity region C2. As a result, in the electrostatic capacity detecting sensor according to the embodiment, the width of the column wiring is wider than that of the first embodiment. In addition, since the first electrostatic capacity region C1 and the second electrostatic capacity region C2 are wider than those of the first embodiment, the S/N ratio of the level of the detecting signal are enlarged. Furthermore, since the column wiring or the row wiring can be widened without widening the respective wiring intervals of the detecting electrodes 13 and the driving electrodes 32, the resolution of the electrostatic capacity detecting sensor is not deteriorated.

Still furthermore, in the electrostatic capacity detecting sensor shown in FIGS. 12 and 13, an electric field between the driving electrode 32 and the detecting electrode 13 can be shielded and a capacity value Cc of a parasitic capacitor 103 between the driving electrode 32 and the detecting electrode 13 can be eliminated. Therefore, in the driving electrode 32 and the detecting electrode 13, a time constant and the effect of the wiring delay can be further reduced, as compared with the first embodiment.

For example, in the electrostatic capacity detecting sensor shown in FIGS. 12 and 13, the respective capacity values become Ca=738 fF, Cb=456 fF, Cc=0 fF, and C0=456 fF when the insulating film 3 and the passivation film 6 are made of the same material as that of the first embodiment, and the line width of the driving electrode 32 is 41 μm. Also, if the capacity value Cf=1 pF and V1=5 V, Vo(off)=1.41 V when an object to be detected 9 is sufficiently separated from a passivation film 6, and Vo(on)=1.02 V when the object to be detected 9 contacts the passivation film 6, thereby, the output change of the difference voltage varying with the existence of the object to be detected 9 ΔVo=0.39 V can be obtained.

### Fifth Embodiment

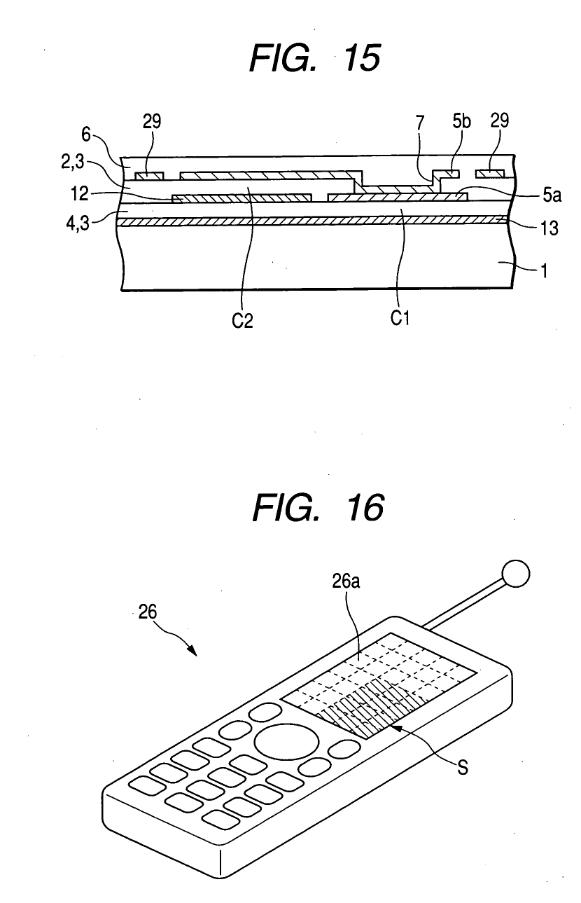

A fifth embodiment of the invention will be described with reference to FIGS. 14 and 15. FIG. 14 is an enlarged plan view of a detecting portion of a capacity detecting sensor according to a fifth embodiment of the invention, and FIG. 15 is a cross-sectional view taken along line E-E of FIG. 14. In the fifth embodiment shown in FIGS. 14 and 15, the same portions as those of the first embodiment shown in FIGS. 1 to 3 are denoted by the same reference numerals, and thus, their description will be omitted.

The sensor shown in FIGS. 14 and 15 is different from the first embodiment in that an earth wiring 29 composed of a third conductive film is provided to surround a floating electrode 5 through a passivation film 6.

With the electrostatic capacity detecting sensor shown in FIGS. 14 and 15, a surface potential can be fixed to the earth wiring 29, and the effect of noise can be prevented efficiently, thereby the resistance against static electricity can be improved.

In addition, since the earth wiring 29 can be provided simultaneously during the step of forming an upper electrode 5b of the floating electrode 5, it can be easily formed without increasing the number of fabricating steps.

Meanwhile, the invention is not limited to the embodiments. For example, although the passivation film 6 is made by laminating SiₓN_{y} (silicon nitride film) such as Si₃N₄ in the embodiments, the passivation film can be made of the other materials such as one selected from SiNₓ, fluorine compound, polyimide, TiO₂ (titanium oxide) or the like in consideration of the surface strength, water repellency, and sensitivity.

In addition, the invention is not limited to the embodiments, and the invention can include no passivation film 6 or the passivation film 6 can be provided partially. With the electrostatic capacity detecting sensor having the above structure, the difference voltage varying with the existence of the object to be detected 9 can be enlarged. Furthermore, it is effective to make the passivation film 6 thin, for example, 3 μm or less, or to form the passivation film 6 with a material having a high permittivity such as TiO₂ or the like in order to enlarge the difference voltage varying with the existence of the object to be detected 9.

Still furthermore, the invention is not limited to the embodiments, and the position of the detecting electrode cam be exchanged with that of the driving electrode. Meanwhile, if the driving electrode is placed above the detecting electrode, the effect of noise is diminished, comparing with the case where the detecting electrode is placed above the driving electrode.

Still furthermore, instead of the glass substrate 1, a plastic substrate or the like can be used.

Still furthermore, the electrostatic capacity detecting sensor according to the invention can be formed on a display surface of a portable phone 26 shown in FIG. 16. Recently, it is considered to pay bills with the portable phone 26. In this case, if the electrostatic capacity detecting sensor S is formed in the portable phone 26, a fingerprint marked on the electrostatic capacity detecting sensor S can be detected accurately, and the detected fingerprint is compared with fingerprint data that are previously registered, thereby the owner can be authenticated correctly. FIG. 16 shows an example where the electrostatic capacity detecting sensor S is formed on the display screen 26a of the portable phone 26 composed of liquid crystal or the like. In this case, if the entire electrostatic capacity detecting sensor S is made of a transparent material that transmits light, it is not required to dispose a fingerprint sensor S at a portion other than the display screen 26a, and thus, the size of the portable phone can be reduced.

Since the electrostatic capacity detecting sensor according to the invention includes the first electrodes which extend from the row wiring lines; the second electrodes which extend from the column wiring lines and are provided on a different layer from that of the first electrode; the third electrode which is electrically independent from the first electrodes and the second electrodes through an insulating film; a first electrostatic capacity region formed between the first electrodes and the third electrode; and a second electrostatic capacity region formed between the second electrodes and the third electrode, in which the change in distance between an object to be detected and the third electrode is detected by the change of displacement current between the first electrodes and the second electrodes, and the electrostatic capacity detecting sensor can secure a space, in which the column wiring lines and the row wiring lines can be disposed widely even when, at the intersections between the column wiring lines and the row wiring lines, the first electrostatic capacity region is formed between the first electrodes and the third electrode and the second electrostatic capacity region is formed between the second electrodes and the third electrode. Therefore, disconnection of wiring lines due to electrostatic discharge rarely occurs and a detecting signal having a large S/N ratio and a high resolution can be obtained.

1. An electrostatic capacity detecting sensor, in which row wiring lines and column wiring lines are arranged in a matrix on a substrate, comprising:
first electrodes which extend from the row wiring lines at intersections between the row wiring lines and the column wiring lines;
second electrodes which extend from the column wiring lines and are formed on a different layer from that of the first electrodes;
a third electrode which is electrically independent from the first electrodes and the second electrodes through an insulating film;
a first electrostatic capacity region formed between the first electrodes and the third electrode; and
a second electrostatic capacity region formed between the second electrodes and the third electrode,
wherein a change in distance between an object to be detected and the third electrode is detected by change of displacement current between the first electrodes and the second electrodes.

2. The electrostatic capacity detecting sensor according to claim 1,
wherein the third electrode is provided above the first electrodes and the second electrodes.

3. The electrostatic capacity detecting sensor according to claim 1,
wherein the third electrode is formed between the first electrodes and the second electrodes through the insulating film.

4. The electrostatic capacity detecting sensor according to claim 3,
wherein a portion of the third electrode is exposed to a surface through a contact hole formed in the insulating film.

5. The electrostatic capacity detecting sensor according to claim 1,
wherein the third electrode vertically extends to surround upper electrodes of the first electrodes and the second electrodes.

6. The electrostatic capacity detecting sensor according to claim 1,
wherein the third electrode is formed on the same layer of the upper electrodes of the first electrodes and the second electrodes and a layer located higher than the upper electrodes while conducted with one another.

7. The electrostatic capacity detecting sensor according to claim 1,
wherein the substrate is made of a transparent material, and the first electrodes, the second electrodes, and the third electrode are made of a transparent conductive material.
